(19) United States
(12) Patent Application Publication
(10) Pub. No.: US 2013/0049129 A1
(43) Pub. Date: Feb. 28, 2013

(54) SEMICONDUCTOR DEVICE AND MANUFACTURING METHOD THEREOF

(71) Applicants: JUNHONG FENG, BEIJING (CN); Zhenghao Gan, BEIJING (CN)

(72) Inventors: JUNHONG FENG, BEIJING (CN); Zhenghao Gan, BEIJING (CN)

(73) Assignee: SEMICONDUCTOR MANUFACTURING INTERNATIONAL (BEIJING) CORPORATION, BEIJING (CN)

(21) Appl. No.: 13/326,170

(22) Filed: Dec. 14, 2011

(30) Foreign Application Priority Data
Aug. 26, 2011 (CN) 201110248458.5

(51) Int. Cl. H01L 27/092; H01L 21/28

(52) U.S. Cl. 257/369; 438/585; 257/E27.062; 257/E21.19

(57) ABSTRACT

The present invention relates to a semiconductor device having a P-channel semiconductor region and a manufacturing method therefor. The method comprises: forming a gate dielectric layer on a substrate; forming a gate material layer on the gate dielectric layer; blanket pre-doping the gate material layer to introduce an N-type dopant thereto; and pre-doping with fluorine a region of the gate material layer designed to be said P-channel semiconductor device, such that the fluorine dopes an interface between the substrate and the region of the gate dielectric layer designated to be said P-channel semiconductor device. The semiconductor device further comprises an N-type semiconductor region in said gate material layer.

### CROSS-REFERENCE TO RELATED APPLICATIONS

This application claims priority to Chinese Patent Application No. 201110248458.5, filed on Aug. 26, 2011 and entitled “Semiconductor Device and Manufacturing Method thereof”, which is incorporated herein in its entirety by reference.

### FIELD OF THE INVENTION

The present invention relates to the field of semiconductor fabrication techniques, and more specifically, relates to a semiconductor device and a manufacturing method thereof.

### DESCRIPTION OF THE RELATED ART

With the continuous reduction in size of ultra-large scale integrated circuits (ULSI), gate dielectrics in a MOS (metal-oxide-semiconductor) device are being scaled down in thickness to achieve higher device performance. However, the threshold voltage Vt of a device is limited, and cannot be unlimitedly decreased. Currently, the gate voltage Vg is about 1.0V, which has reached a plateau.

The scaling down of gate dielectric thickness with a high rate and scaling down of threshold voltage with a lower rate has resulted in degradation of the device performance such as the Negative Bias Temperature Instability (NBTI) so that the device fails to meet the specification. As known by those skilled in the art, NBTI refers to the performance degradation of a device as temperature increase of temperature, which is a key characteristic for device reliability. The better the performance regarding negative bias temperature instability of a device the less the device is influenced by the temperature, that is, the device is more reliable.

On the other hand, as an option for improving the NBTI performance, fluorine (F) can be introduced so as to create strong Si—F bonds at the Si/SiO₂ interface.

Terence B. Hook, et al., “The Effects of Fluorine on Parametrics and Reliability in a 0.18-μm 3.5/6.8 nm Dual Gate Oxide CMOS Technology”, IEEE Transactions on Electron Devices, Vol. 48, No. 7, June 2001, pp 1346-1353, describes that fluorine can be introduced for improving the NBTI performance of devices, and that the higher the fluorine dose(concentration) in a gate oxide, the less the NBTI shift. In U.S. Pat. No. 6,358,865, it has proposed that fluorine be implanted into the silicon lattice/substrate before forming oxide regions thereon so as to improve the device performance.

However, pure fluorine implantation may cause bubble defects when the dosage is too high. In other words, the fluorine dosage is limited if pure fluorine implantation is employed, and thus, the improvement of the NBTI performance by such fluorine implantation is limited.

Thus, it is desirable to improve the process to improve reliability.

### SUMMARY OF THE INVENTION

As is known by those of ordinary skill in the art, the MOS device is a general term for a field-effect semiconductor device. The MOS device can comprise N-type and P-type MOS semiconductor devices (which can also can be referred to as N-channel and P-channel semiconductor devices, respectively) and a CMOS device comprises both N-type and P-type MOS devices.

An object of the present invention is to at least mitigate or address the above problems existed in the prior art. Another object of the present invention is to provide a method of manufacturing a semiconductor device that is capable of improving device reliability, especially the NTBI performance. A further object of the present invention is to introduce fluorine to improve device NTBI performance, while mitigating or eliminating the influence of fluorine implantation on PMOS device performance. A further object of the present invention is to mitigate or eliminate the influence of fluorine implantation on the subsequent manufacturing process steps of a device.

According to an embodiment of the present invention, there is provided a method of manufacturing a semiconductor device, the semiconductor device comprising a P-channel semiconductor device comprising: forming a gate dielectric layer on a substrate; forming a gate material layer on the gate dielectric layer; blanket-pre-doping the gate material layer so as to introduce an N-type dopant thereto; and pre-doping a region of the gate material layer for the P-channel semiconductor device with fluorine, such that fluorine can be introduced to an interface between the substrate and the region of the gate dielectric layer for the P-channel semiconductor device.

In one embodiment of the invention, the pre-doping of a region of the gate material layer for the P-channel semiconductor device with fluorine comprises forming a patterned mask on the gate material layer so as to expose the region of the gate material layer for the P-channel semiconductor device and pre-doping the exposed region of the gate material layer with fluorine.

In one embodiment of the invention, the pre-doping with fluorine is performed by ion implantation with a P-type fluorine dopant.

In one embodiment of the invention, the P-type fluorine dopant comprises BF₂.

In one embodiment of the invention, the ion implantation is performed with an energy of 1 keV to 20 keV and a dosage of 1×10¹³ to 1×10¹⁶ atom/cm².

In one embodiment of the invention, the semiconductor device further comprises an N-channel semiconductor device, wherein the gate material layer further comprises a region for the N-channel semiconductor device.

In one embodiment of the invention, the P-type impurities in the P-type fluorine dopant is partially used to offset the influence on the region of the gate material layer for the P-channel semiconductor device exerted by the introduced N-type dopant and is partially used to adjust the depletion of the region of the gate material layer for the P-channel semiconductor device.

In one embodiment of the invention, the gate material comprises poly-silicon.

In one embodiment of the invention, said method further comprises patterning the gate material layer to form a gate, wherein the patterning the gate material layer is performed after the fluorine pre-doping.

In one embodiment of the invention, the gate comprises a dummy gate.

According to another aspect of the present invention, there is provided a semiconductor device, including a P-channel semiconductor device, the semiconductor device comprising: a substrate; a gate dielectric layer on the substrate; a gate material layer on the gate dielectric layer, wherein a region of the gate material layer for the P-channel semiconductor device is doped with P-type fluorine dopant and N-type dopant; and wherein, fluorine (F) is introduced from the region of the gate material layer for the P-channel semiconductor device into an interface between the substrate and a region of the gate dielectric layer for the P-channel semiconductor device.

The P-type impurities in the P-type fluorine dopant can be partially used to offset the influence on the region of the gate material layer for the P-channel semiconductor device exerted by introducing an N-type dopant and can be further partially used for adjusting the depletion of the region of the gate material layer for the P-channel semiconductor device.

In some embodiments, the semiconductor device further comprises an N-channel semiconductor device, wherein, the gate material layer further comprises a region for the N-channel semiconductor device.

The P-type fluorine dopant can be doped into the gate material layer by ion implantation.

The P-type fluorine dopant can comprise BF₂.

The ion implantation can be performed with an energy of 1 keV to 20 keV and a dosage of 1×10¹³ to 1×10¹⁶ atom/cm².

The gate material can comprise poly-silicon.

The gate material layer can be patterned to form a gate, wherein the patterning of the gate material layer is performed after the doping with the P-type fluorine dopant.

In some embodiments, the gate comprises a dummy gate.

According to an embodiment of the present invention, there is provided a novel method of manufacturing a semiconductor device. According to one embodiment of the present invention, device reliability, especially the NTBI performance, can be improved; which in turn can prolong the NBTI life of the device. According to another embodiment of the present invention, the introduced P-type impurities can offset or cancel the influence on the gate material layer exerted by the N-type dopant introduced and can also be used to fine-tune the depletion region of the PMOS gate material layer. As such, a larger dosage of fluorine can be introduced into the Si/SiO₂ interface, thereby improving NBTI performance of the device. According to a further embodiment of the present invention, the influence on the subsequent manufacturing process steps of the device, exerted by the introduction of fluorine can be mitigated or eliminated such that the solution of the present invention can be combined with the existing process cycles without substantively changing the process parameters of the subsequent process cycles.

The present invention is very useful in advanced semiconductor manufacturing technology (e.g. logic device or manufacturing process optimized for logic device), but the present invention is not so limited. In practice, the present invention can be widely used in various other applications.

Further features, advantages and objects of the present invention will become apparent from the following detailed description of exemplary embodiments according to the present invention with reference to the accompanying drawings.

### BRIEF DESCRIPTION OF THE DRAWINGS

The accompanying drawings, which are incorporated in and constitute a part of the specification, illustrate embodiments of the invention and, together with the description, serve to explain the principles of the invention. The present invention can be more clearly understood by reading the following detailed description with reference to the accompanying drawings, in which:

FIGS. 1-3 show steps in a method of manufacturing a semiconductor device according to the embodiments of the present invention.

It is understood that these drawings are merely illustrative in nature and are not intended to limit the scope of the present invention. In the drawings, various components are not drawn to scale or according to their actual shapes. Some of the components (such as, layers or parts) may be enlarged relative to others so as to more clearly show the principles of the present invention. Moreover, details that may obscure the gist of the present invention are not shown in the drawings.

### DESCRIPTION OF THE EMBODIMENTS

The embodiments of the present invention are described in conjunction with the figures.

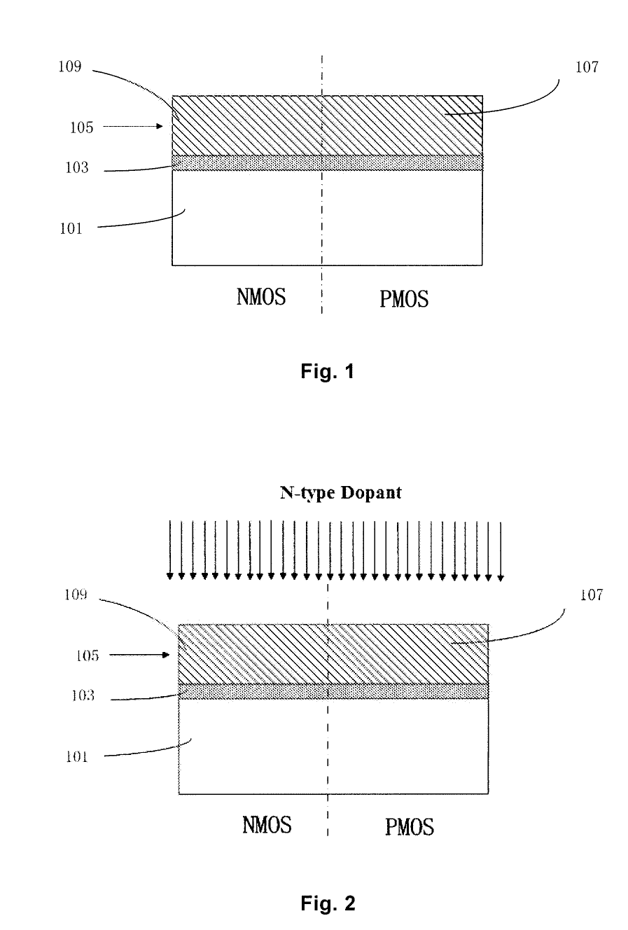

Hereinafter, a method of manufacturing a semiconductor device according to the embodiments of the present invention are described with reference to FIGS. 1-3.

The semiconductor device can comprise a PMOS device. In addition to the PMOS device, the semiconductor device can further comprise an NMOS device (as shown in FIG. 1) and/or any other active or passive device (not shown).

As shown in FIGS. 1-3, the reference “PMOS” corresponds to a PMOS device, while the reference “NMOS” corresponds to an NMOS device. In addition, although the NMOS device is shown as abutting the PMOS device in some of the figures, it is merely illustrative and not limiting. The NMOS device or other devices also can be separate from the PMOS device.

Further, for the sake of clarity, N-well or P-well field oxide isolation or trench isolation (e.g. STI) are not shown in the figures, because these are known by those of ordinary skill in the art and are not part of the present invention. Similarly, in the following descriptions, objects, components, steps or the like that are not features of the present invention and are not described.

As shown in FIG. 1, a gate dielectric layer 103 is formed on a substrate 101, for example, a silicon substrate (such as, a mono-crystalline silicon substrate or a silicon-on-insulator (SOI) substrate). A gate material layer 105 is formed on the gate dielectric layer 103. As to the material of the gate dielectric layer 103, preferred materials can be, for example, silicon oxide, silicon nitride, silicon oxynitride, silicon nitride oxide, high-k dielectric, or a stack of layers of the above materials. The material of the gate material layer 105 can be poly-silicon, for example.

In an example of the present invention, said semiconductor device can comprise a P-channel semiconductor device. In other embodiments, said semiconductor device can further comprise an N-channel semiconductor device in addition to the P-channel semiconductor device. In such a case, the gate material layer 105 can also comprise a region 109 for the N-channel semiconductor device, in addition to a region 107 for the P-channel semiconductor device. It should be understood that, this is merely illustrative. In some embodiments, said semiconductor device can further comprise other devices.

Thereafter, a pre-doping for introducing an N-type dopant is performed, so as to introduce the N-type dopant (e.g. phosphor (P)) into the gate material layer 105, for example, by means of ion implantation or surface diffusion. As shown in FIG. 2, said pre-doping for introducing N-type dopant can be a blanket doping using ion implantation (a doping without use of mask) ; that is to say, a pre-doping for introducing N-type dopant is performed over the entire gate material layer 105 without use of mask.

Then, a pre-doping of fluorine is performed for the region 107 of the gate material layer 105 for the P-channel semiconductor device, such that fluorine can be introduced into an interface between the substrate and the region of the gate dielectric layer for the P-channel semiconductor device. For example, strong Si—F bonds are generated at the Si/SiO₂ interface.

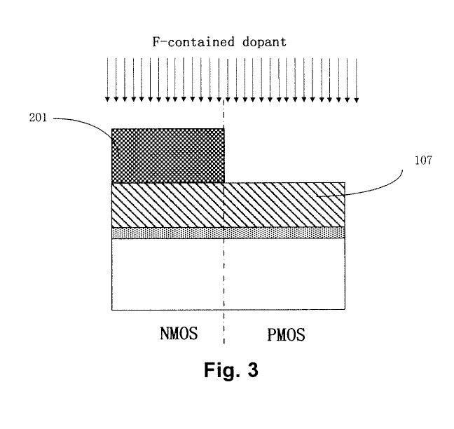

In a particular embodiment of the present invention, as shown in FIG. 3, the step of performing said pre-doping of fluorine can comprise: forming a patterned mask 201 on the gate material layer 105, so as to expose only the region 107 of the gate material layer 105 for the P-channel semiconductor device; and then performing fluorine pre-doping on the exposed region 107 of the gate material layer.

The mask can be a resist layer, for example, a photo-resist layer. A patterned resist layer 201 comprising photo-resist layer on the gate material layer 105 can be formed by spin coating or the like followed by photolithography (exposure and development) on the photo-resist layer. The mask can also be a hard mask, for example, silicon nitride or silicon oxide. As is easily understood by those of ordinary skill in the art, the hard mask material layer can be formed over the gate material layer 105 and then is subjected to photolithography and etching, thereby forming the patterned hard mask 201.

In a more particular embodiment of the present invention, said fluorine pre-doping can employ a F₂, CF₄ dopant as well as other fluorine containing compounds, referred to as a “fluorine dopant”. However, herein, P-type fluorine dopant is preferably employed, as it serves as a donor impurity after being doped into the gate material layer. Atypical example of the P-type dopant can comprise, but is not limited to, BF₂.

The pre-doping of fluorine can be performed by implantation (e.g. ion implantation) or diffusion. Preferably, it is performed by ion implantation, because this process can contribute to the distribution of F element on or to the interface between the substrate and the gate dielectric layer (e.g. Si/SiO₂ interface).

When the pre-doping of BF₂ is performed by ion implantation with an energy preferably ranging from about 1 keV to about 20keV and a dosage preferably ranging from about 1×10¹³ to about 1×10¹⁶ atom/cm².

After the pre-doping with fluorine, the gate material layer 105 can be patterned so as to form a gate. Then, subsequent processes such as LDD implantation, gate spacer formation, source and drain formations, etc. can be performed. These subsequent processes are well known in the art, and thus the detailed description thereof will be omitted.

The pre-doping for introducing an N-type dopant also can be performed after the pre-doping of fluorine. According to another embodiment of the present invention, after the formation of the gate material layer 105, the pre-doping with fluorine can be performed first and then the pre-doping for introducing N-type dopant can be performed. Herein, said pre-doping for introducing N-type dopant can be a blanket doping without use of a mask (e.g. the mask 201 was removed). In another example, the mask 201 can remain; that is to say, said pre-doping for introducing N-type dopant is performed with the mask 201. Then, the gate material layer 105 can be patterned so as to form a gate.

As described above, the pre-doping for introducing an N-type dopant can be a blanket pre-doping that is performed over the entire gate material layer with the N-type dopant. In such a case, since a blanket pre-doping is employed, a reticle on the surface and the corresponding processes can be saved as compared with the case where the doping (pre-doping) for introducing N-type dopant is performed separately for the regions used for the PMOS device and the NMOS device.

In addition, when performing said pre-doping of fluorine with the P-type fluorine dopant, the introduced P-type impurities can be partially used to offset the influence on the gate material layer exerted by the introduced N-type dopant and can partially be used for adjusting the depletion of the PHOS gate material layer. As such, a larger dosage of fluorine can be introduced into the Si/SiO₂ interface, thereby improving NBTI performance.

According to another aspect of the present invention, there is provided a semiconductor device including a P-channel semiconductor device, the semiconductor device comprising: a substrate; a gate dielectric layer on the substrate; and a gate material layer on the gate dielectric layer, wherein a region of the gate material layer for the P-channel semiconductor device is doped with P-type fluorine dopant and N-type dopant; and wherein, fluorine (F) is introduced from the region of the gate material layer for the P-channel semiconductor device into an interface between the substrate and a region of the gate dielectric layer for the P-channel semiconductor device.

Preferably, the P-type impurities in the P-type fluorine dopant are partially used to offset the influence on the region of the gate material layer for the P-channel semiconductor device exerted by the introduced N-type dopant introduced, and are also partially used for adjusting the depletion of the region of the gate material layer for the P-channel semiconductor device.

In some embodiments, the semiconductor device further comprises an N-channel semiconductor device, wherein the gate material layer further comprises a region for the N-channel semiconductor device.

The P-type fluorine dopant can be doped into the gate material layer by ion implantation.

The P-type fluorine dopant can comprise BF₂.

The ion implantation can be performed with an energy of 1 keV to 20 keV and a dosage of 1×10¹³ to 1×10¹⁶ atom/cm².

The gate material can comprise poly-silicon. a. The gate material layer can be patterned to form a gate, wherein the patterning of the gate material layer is performed after the doping with the P-type fluorine dopant.

In some embodiments, the gate comprises a dummy gate.

As would be understood by those of ordinary skill in the art in light of the teachings herein, the features of the present invention can readily be applied to the gate-last process sequence. As such the gate shown in the above embodiments is adaptable to be a dummy gate. After introducing fluorine into the dummy gate such that the fluorine exists at the Si—SiO₂ interface, the dummy gate can be removed at a proper time in the subsequent processes and can be replaced with a metal gate. In such a case, the pre-doping to introduce an N-type dopant is not required in some examples. Since the gate-last process sequence, as well as subsequent processes, are well known in the art, detailed descriptions thereof are omitted herein.

The embodiments of the present invention have been described as above with reference to the drawings. It is understood, however, that these embodiments are merely illustrative and not intended to limit the scopes of the invention. These embodiments can be combined without going beyond the scope of the present invention. In addition, these embodiments and details thereof can be modified by those of ordinary skill in the art in light of the teachings herein, without departing from the scope or intent of the present invention. Therefore, all such modifications are within the spirit and scope of the present invention which is defined by the attached claims.

What is claimed is:

1. A method of manufacturing a semiconductor device, comprising a P-channel semiconductor device, comprising:
forming a gate dielectric layer on a substrate;
forming a gate material layer on the gate dielectric layer;
blanket-pre-doping the gate material layer so as to introduce an N-type dopant thereto; and
pre-doping a region of the gate material layer for the P-channel semiconductor device with fluorine, such that fluorine is introduced to an interface between the substrate and the region of the gate dielectric layer for the P-channel semiconductor device.

2. The method of claim 1, wherein pre-doping a region of the gate material layer prior to forming the P-channel semiconductor device with fluorine comprises:
forming a patterned mask on the gate material layer, exposing the region of the gate material layer for the P-channel semiconductor device; and
pre-doping the exposed region of the gate material layer with fluorine.

3. The method of claim 1, wherein the pre-doping with fluorine is performed by ion implantation with a P-type fluorine dopant.

4. The method of claim 3, wherein the P-type fluorine dopant comprises BF₂.

5. The method of claim 4, wherein the ion implantation is performed with an energy of 1 keV to 20 keV and a dosage of 1×10¹³ to 1×10¹⁶ atom/cm².

6. The method of claim 1, wherein the semiconductor device further comprises an N-channel semiconductor device, formed in a region of the gate material layer.

7. The method of claim 1, wherein the P-type impurities in the P-type fluorine dopant functions in part to offset the effect on the P-channel semiconductor device region of the gate material layer caused by introducing the N-type dopant, and functions in part to adjust the depletion of the region of the gate material layer comprising the P-channel semiconductor device.

8. The method of claim 1, wherein the gate material comprises poly-silicon.

9. The method of claim 1, wherein the method further comprises patterning the gate material layer to form a gate, wherein the patterning of the gate material layer is performed after the pre-doping with fluorine.

10. The method of claim 1, wherein the gate comprises a dummy gate.

11. A semiconductor device, said semiconductor device including a P-channel semiconductor device and comprising:
a substrate;
a gate dielectric layer on the substrate; and
a gate material layer on the gate dielectric layer,
wherein, a region of the gate material layer designated to be the P-channel semiconductor device is doped with a P-type fluorine dopant and an N-type dopant; and
wherein, the fluorine (F) introduced into the P-channel semiconductor device region of the gate material layer further dopes an interface between the substrate and a region of the gate dielectric layer for the P-channel semiconductor device.

12. The semiconductor device of claim 11, wherein the P-type impurities in the P-type fluorine dopant functions in part to offset the effect on the P-channel semiconductor device region of the gate material layer and further functions in part to partially adjust the depletion of the P-channel semiconductor device region of the gate material layer.

13. The semiconductor device of claim 11, wherein the semiconductor device further comprises an N-channel semiconductor device, wherein the gate material layer further comprises a N-channel semiconductor device region.

14. The semiconductor device of claim 11, wherein the P-type fluorine dopant is doped into the gate material layer by ion implantation.

15. The semiconductor device of claim 14, wherein the P-type fluorine dopant comprises BF₂.

16. The semiconductor device of claim 14, wherein the ion implantation is performed with an energy of 1 keV to 20 keV and a dosage of 1×10¹³ to 1×10¹⁶ atom/cm².

17. The semiconductor device of claim 11, wherein the gate material comprises poly-silicon.

18. The semiconductor device of claim 11, wherein the gate material layer is patterned to form a gate, after doping with the P-type fluorine dopant.

19. The semiconductor device of claim 18, wherein the gate comprises a dummy gate.
